(19) United States
(12) Patent Application Publication
(10) Pub. No.: US 2010/0262419 A1
(43) Pub. Date: Oct. 14, 2010

(54) METHOD OF CONTROLLING COMMUNICATIONS BETWEEN AT LEAST TWO USERS OF A COMMUNICATION SYSTEM

(75) Inventors: Werner Paulus Josephus De Bruijn, Eindhoven (NL); Aki Sakari Harma, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/747,173

(22) PCT Filed: Dec. 10, 2008
(86) PCT No.: PCT/IB2008/055196

§ 371 Date: Jun. 10, 2010

(30) Foreign Application Priority Data
Dec. 17, 2007 (EP) 07123343.1

(51) Int. Cl. H03G 3/00; G06F 17/27

(52) U.S. Cl. 704/9; 381/107; 704/E15.04

(57) ABSTRACT

A communication system includes at least a sound re-production system (13-16,18-20) for audibly reproducing sound communicated by one user to another. A method of controlling communications between at least one first and at least one second user of the communication system includes adjusting the sound reproduction system (13-16,18-20) so as to cause an apparent distance between the other user and a location of an origin of the reproduced sound as perceived by the other user to be adjusted. Data (23,25) representative of at least one indicator of at least an interpersonal relation of the at least one first user and the at least one second user is obtained. The apparent distance is determined at least in part according to a pre-determined functional relationship between an indicator of at least an interpersonal relation and a desired interpersonal distance.

### FIELD OF THE INVENTION

The invention relates to a method of controlling communications between at least one first and at least one second user of a communication system,

wherein the communication system includes at least a sound reproduction system for audibly reproducing sound communicated by one of the first and second users to the other of the first and second users.

The invention also relates to a system for controlling communications between at least one first and at least one second user of a communication system,

wherein the communication system includes at least a sound reproduction system for audibly reproducing sound communicated by one of the first and second users to the other of the first and second users.

The invention also relates to a computer programme.

### BACKGROUND OF THE INVENTION

US 2004/0109023 discloses a network connection configuration in which game apparatuses operated by players and connected to a network node are controlled by a server apparatus. Voice chats between game apparatuses connected to the network node are controlled by the server apparatus. A main CPU of a game apparatus obtains player operating signals input from a controller via a peripheral interface, and performs game processing. The main CPU calculates positions (co-ordinates), travel distance or speed, etc. of objects in virtual space in accordance with an input by the controller. Voice information sent from the server apparatus is stored in a buffer through a modem. A sound processor reads voice information sequentially in the order stored in the buffer and generates a voice signal and outputs it from a speaker. The server apparatus adjusts the output volume of the voice chat to reflect the positional relationship of characters displayed in the game screen and operated by the players.

A problem of the known method and system is that users position objects operated by them according to considerations unrelated to the subject of their chat. As a consequence of this, misunderstandings can occur, and the conversation can assume an artificial character.

### SUMMARY OF THE INVENTION

It is an object of the invention to provide a method, system and computer programme that are relatively effective at imparting to voice communications between remote users of a communication system the character of a face-to-face personal conversation.

This object is achieved by the method according to the invention, which includes:

obtaining data representative of at least one indicator of at least an interpersonal relation of the at least one first user to the at least one second user; and

adjusting the sound reproduction system so as to cause an apparent distance between the other user and a location of an origin of the reproduced sound as perceived by the other user to be adjusted, the apparent distance being determined at least in part according to a pre-determined functional relationship between an indicator of at least an interpersonal relation and a desired interpersonal distance.

It has been shown that, in natural day-to-day conversation, the interpersonal distance that two persons having a conversation feel most comfortable with depends on various factors, most notably the social relationship between the two persons and the nature of their conversation. The latter might include factors related to the content of the conversation and the emotional state of the persons. Knowledge about this dependence is built into the pre-determined relationship, which is thus used to give the conversation carried out through the communication system a more natural character.

In an embodiment, at least one of the at least one indicator is dependent on the identities of the first and second users.

An effect thereof is that automatic characterisation is allowed of the interpersonal relation between the first and second users, based on their identities. The identities of the users of a communication system are generally known, because they are generally constitutive for establishing a connection.

In an embodiment, at least part of the data representative of at least one indicator is based on data provided by at least one of the first and second users.

An effect thereof is that a suitable indicator is provided in an easy, efficient manner.

In an embodiment, the data provided by at least one of the first and second users includes data associating the other of the first and second users with one of a set of relationship categories, each associated with data representative of at least one indicator value.

An effect thereof is that efficient retrieval is made possible of the data representative of at least one indicator of at least an interpersonal relation of the first user to the second user. There is a finite number of indicator values, at least initially, on the basis of which the signals for adjusting the apparent distance can be determined.

A variant includes selecting at least one indicator value in preference to the at least one indicator value associated with the one relationship category in response to user input.

An effect thereof is that a user is allowed to fine-tune or override the settings associated with the selected category. This solves the problem that the relationship between two users can vary according to circumstances (people characterised as friends can fall out or make up, for example). To achieve a system that imparts to voice communications between remote users of a communication system the character of a face-to-face personal conversation, the possibility of adaptation to temporarily changed circumstances is provided in this embodiment.

In an embodiment, data representative of at least one indicator is stored in association with contact details for at least one of the first and second users.

An effect is an improvement in the efficiency with which the method can be implemented in association with an actual voice communication system. Selection of the communication partner by a user is sufficient for both the details for establishing a connection and the details for adjusting the apparent distance perceived by at least one of the communication partners to be retrieved.

In an embodiment, data representative of at least one indicator is obtained by analysing at least part of at least one signal communicating sound between the first and the second user.

An effect thereof is that a method is provided that is relatively effective in adapting to changing aspects of the relationship between two communication partners.

A variant includes semantically analysing contents of speech communicated between the first and the second user.

This type of analysis is relatively reliable for establishing how one person is disposed towards another. Thus, the interpersonal relation of that person with the other is determined relatively effectively, and the communications between the persons give a relatively realistic impression of a conversation conducted face-to-face.

A further variant includes analysing at least one signal property of the at least part of at least one signal communicating sound between the first and second user.

This type of analysis can be performed relatively easily and in a computationally relatively efficient manner. It does not rely on a thesaurus, is generally independent of language characteristics, and still relatively effective. Tempo and volume, for example, are relatively reliable indicators of an interpersonal relation of the speaker with the addressee.

An embodiment of the method of controlling communications includes adjusting the sound reproduction system so as to cause an apparent location of the origin of the reproduced sound as perceived by the other user to be adjusted in accordance with the interpersonal distance determined according to the functional relationship.

An effect thereof is a more realistic impression of being spoken to by a person than can be achieved, for example, by simple volume adjustment. A sense of distance is conveyed well when the sound appears to come from a certain point.

In an embodiment, the communication system includes a further sound reproduction system, for audibly reproducing sound communicated by the other user to the one user, wherein both sound reproduction systems are adjusted so as to cause an apparent distance between the one user and a location of an origin of reproduced sound as perceived by the one user and an apparent distance between the other user and a location of an origin of reproduced sound as perceived by the other user to be adjusted to generally the same value.

An effect thereof is that the communications are made more realistic by removing any dissonance between the impression given to the first user and that given to the second user.

According to another aspect of the invention, there is provided a system for controlling communications between at least one first and at least one second user of a communication system,

wherein the communication system includes at least a sound reproduction system for audibly reproducing sound communicated by one of the first and second users to the other of the first and second users, and wherein the system for controlling communications is configured to:

obtain data representative of at least one indicator of at least an interpersonal relation of the at least one first user with the at least one second user, and

to adjust the sound reproduction system so as to cause the apparent distance between the other user and a location of an origin of the reproduced sound as perceived by the other user to be adjusted at least in part according to a pre-determined functional relationship between an indicator of at least an interpersonal relation and an interpersonal distance.

An embodiment of the system is configured to execute a method according to the invention.

According to another aspect of the invention, there is provided a computer programme including a set of instructions capable, when incorporated in a machine-readable medium, of causing a system having information processing capabilities to perform a method according to the invention.

### BRIEF DESCRIPTION OF THE DRAWINGS

The invention will be explained in further detail with reference to the accompanying drawings, in which:

FIG. 1 is a schematic diagram of a communication system;

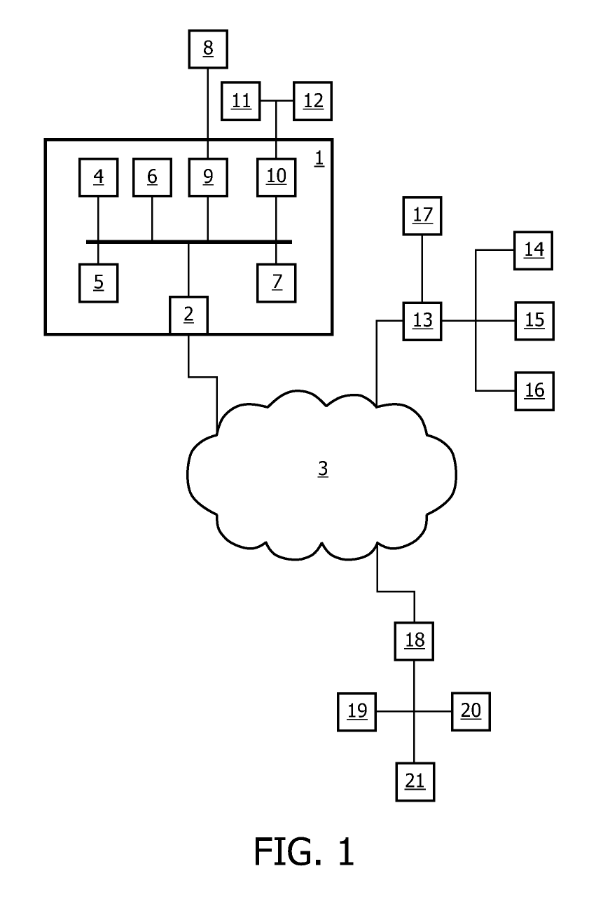

FIG. 2 is a flow chart of a first embodiment of a method of controlling communications between users of the communication system; and

FIG. 3 is a flow chart of a second embodiment of a method of controlling communications between users of the communication system.

### DETAILED DESCRIPTION OF THE EMBODIMENTS

As an example, a first communication terminal 1 includes a network interface 2 to a data communication network 3. The principles discussed below function in conjunction with a packet-switched network and a connection-oriented network. The data communication network 3 is an IP (Internet Protocol)-based network in one embodiment. In another embodiment, it is a network dedicated to the communication of voice data, e.g. a cellular telephone network. In another embodiment, it is an internetwork of such networks. Accordingly, the first communication terminal 1 can be a mobile terminal, e.g. a cellular telephone handset, a Personal Digital Assistant with a wireless adapter or modem, etc. In another embodiment, the first terminal 1 is a terminal for video telephony or video conferencing, and the network 3 is arranged to carry both audio and video data.

In the illustrated embodiment, the first communication terminal 1 includes a data processing unit 4, memory 5 and user controls 6, such as a keypad, buttons, a pointer device for controlling a cursor on a screen (not shown), etc. In the illustrated embodiment, a token device 7 associated with a subscriber (user) to the voice communication system is associated with the first communication terminal 1. The token device 7 can be a SIM (Subscriber Identity Module) card for a mobile telephone network, for instance.

Voice input is received through a microphone 8 and A/D converter 9. Sound output is provided by means of an audio output stage 10 and first and second earphones 11,12.

The data processing unit 4 and the audio output stage 10 are configured to control the manner in which sound is reproduced by the first and second earphones 11,12 such that the apparent location of an origin of sound as perceived by a user wearing the earphones 11,12 is adjusted to a target value. Techniques for adjusting the apparent location of the origin of sound are known, for example Head-Related (or Anatomical) Transfer Function (HRTF) processing, or techniques that rely on control of the direct/reverberant ratio. Examples of a system for three-dimensional presentation of audio are given in WO 96/13962, WO 95/31881 and U.S. Pat. No. 5,371,799, amongst others.

A second communication terminal 13 is also connected to the network 3, and likewise provided with a sound reproduction system. This sound reproduction system includes an array of speakers 14-16, of which only a few are shown for illustrative purposes. The second terminal 13 is also provided with a microphone 17.

A third communication terminal 18 is similarly provided, and corresponds substantially to the first terminal 1, being provided with earphones 19,20 and a microphone 21. The sound reproduction system comprised in the third communication terminal 18 and associated peripheral devices is similar to that of the first terminal 1.

The sound reproduction system of the second communication terminal 13 is also configured such that the apparent location of an origin of sound as perceived by a user situated in the vicinity of the speakers 14-16 is adjustable. In a first implementation, use is made of a set of speakers 14-16 including highly directional speakers, which can beam sound towards a user. By varying the particular sub-combination of speakers that is used and/or the sound reproduction volume, at least the apparent distance between the listener and the perceived origin of sound is variable. The principles of construction of a suitable highly directional loudspeaker are described in Peltonen, T., “Panphonics Audio Panel White Paper”, version 1.1 rev JSe, 7 May 2003, retrieved from the Internet at http://www.panphonics.fi on 22 Nov. 2007. In a second embodiment, the sound reproduction system associated with the second terminal 13 makes use of Wave Field Synthesis, a technique for reproducing virtual sound sources. Wave Field Synthesis techniques can be used to create virtual sound sources both in front of and behind the speakers 14-16. This technique is described more fully in Berkhout, A. J., “A holographic approach to acoustic control”, J. Audio Eng. Soc., 36 (12), 1988, pp. 977-995, as well as in Verheijen, E., “Sound reproduction by Wave Field Synthesis, Ph.D. Thesis, Delft Technical University, 1997. In a third embodiment, the sound reproduction system associated with the second terminal 13 makes use of an array processing technique called beam forming. One can use standard delay-and-sum beam forming, described e.g. in Van Veen, B. E. and Buckley, K., “Beamforming: a versatile approach to spatial filtering”, IEEE ASSP Mag., 1988. One can also use a numerical optimisation procedure to derive a set of digital Finite Impulse Response (FIR) filters, one for each of the speakers 14-16, that realise a desired virtual source of sound, possibly incorporating compensations for the characteristics of the speakers 14-16 and influences of the room. This is described more fully in the above-mentioned article by Van Veen and Buckley, and also in Spors, S. et al., “Efficient active listening room compensation for Wave Field Synthesis”, 116^{th} Conference of the Audio Eng. Soc., paper 6619, 2004.

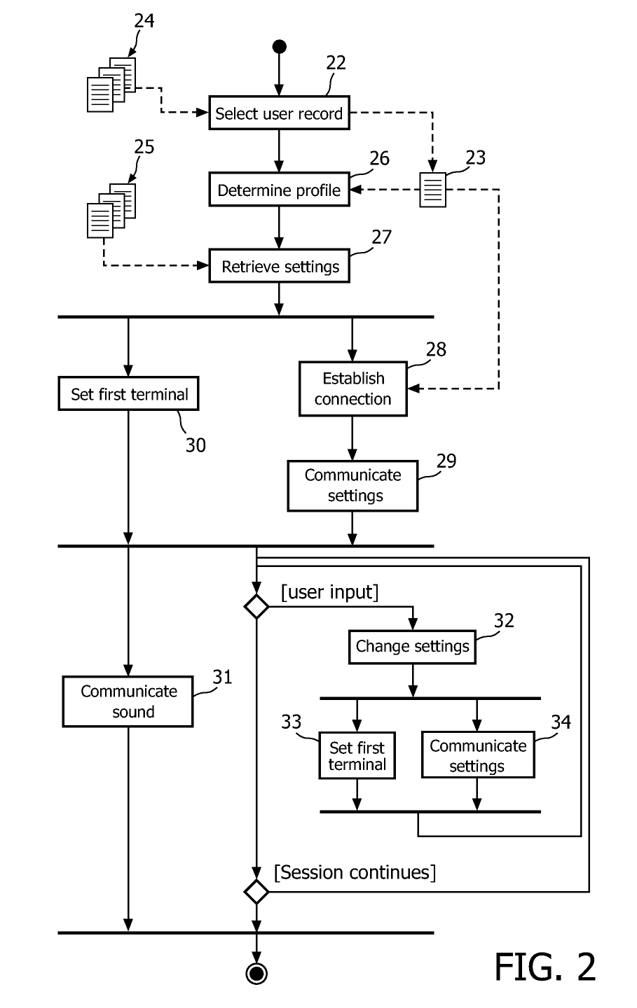

FIG. 2 illustrates a first embodiment of a method of controlling communications between a user of the first terminal 1 and one or more users of one or both of the second and third terminals 13,18.

In a first step 22, a particular user record 23 is selected from among a plurality of user records 24 stored in memory 5 or a memory module comprised in the token device 7. The user record 23 includes contact details for a selected user, enabling a connection to be established or requested to the one of the second and third terminals 13,18 that is associated with the selected user. In the case of an outgoing call, a user of the first terminal 1 selects the user record 23, using the user controls 6. In the case of an incoming call, the user record 23 can be selected using e.g. recognition of the caller's number and searching for it amongst the contact details included in the user records 24.

The selected user record 23 further includes data identifying the right one of a plurality of user profiles 25. In a next step 26, the profile, or category, associated with the selected user is determined. The user of the first terminal 1 is able to assign each of the users identified in the user records 24 to one of several groups with varying degrees of social “closeness”, e.g. ranging from an “intimate” category for the user's partner to a category for total strangers, with an arbitrary number of intermediate levels in between these extremes.

In the illustrated embodiment, data from the appropriate profile is retrieved (step 27) to enable the first terminal 1 to determine data for adjusting the apparent distance between the selected other user and a location of an origin of reproduced sound as perceived by that other user using the second or third terminal 13,18. The data is determined according to a pre-determined functional relationship between the at least one indicator of an interpersonal relation of the first user with the selected second user and an interpersonal distance between two persons. If there is no user record associated with the selected communication partner, a default user profile can be selected from amongst the user profiles 25.

In one embodiment, the data is already provided in the profiles 25, being based on the functional relationship, by the provider of the first terminal 1. In another embodiment, parameters representative of the functional relation are maintained by the first terminal 1, and enable it to carry out a conversion from social indicator values to a target distance value. In yet another embodiment, only social indicator values are retrieved from the user profiles 25 at this step 27, the transformation into a target distance value being carried out in the terminal associated with the selected user.

From social sciences, it is known that in natural day-to-day conversation, the inter-personal distance that people having a conversation feel most comfortable with depends on various factors, most notably the social relationship between the two persons and also the nature of their conversation. The latter might include factors related to the content of their conversation (e.g. private or not), the emotional state of the persons (angry, affectionate, etc.), for example. This is explained more fully in Hall, E. T., “A system for the notation of proxemic behaviour”, American Anthropologist, 65, 1963, pp. 1003-1026.

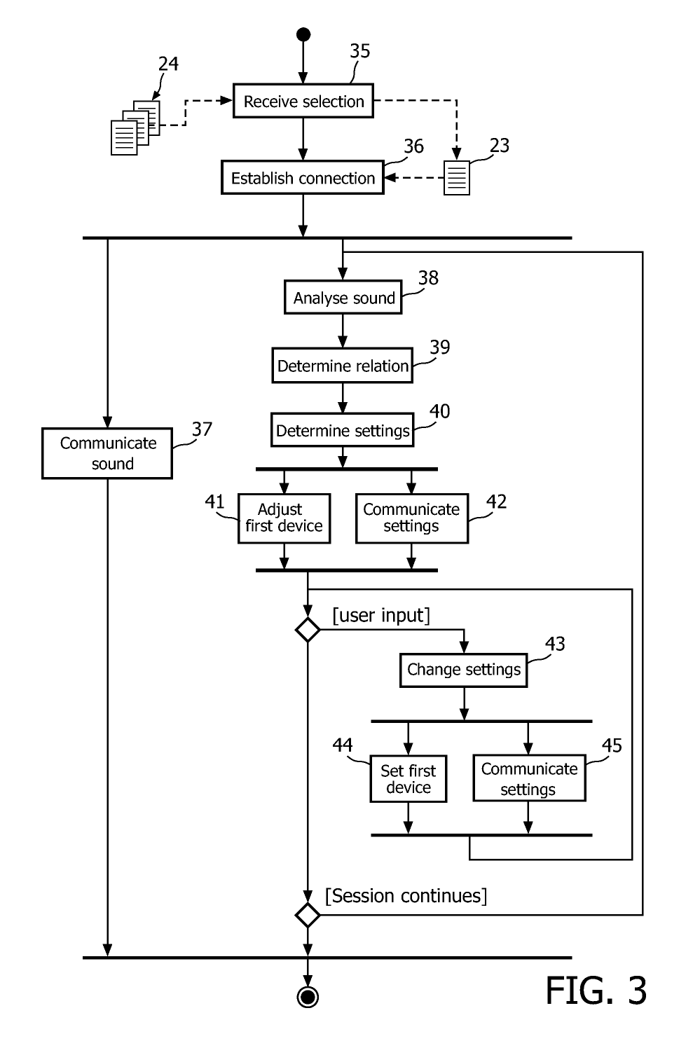

In the embodiment illustrated in FIG. 2, the target value of the perceived distance between at least one of the communication partners and the location of the origin of sound perceived by that person is based on the identities of the first and second users in the first instance. A particular selection of communication partners results in a particular target value of the interpersonal distance. The nature of their conversation is used as an indicator of their (momentary) interpersonal relation in the embodiment of FIG. 3 (to be explained hereinbelow). A further embodiment (not shown) is a combination of the two embodiments.

As outlined in FIG. 2, in the case of an outgoing call, the first terminal 1 establishes a connection (step 28) to the particular one of the second and third terminals 13,18 identified in the user record 23. In the case of an incoming call, this step 28 includes accepting a request from that particular one of the second and third terminals 13,18 to establish the connection.

In the illustrated embodiment, the settings determined previously are communicated (step 29) to, for example, the third terminal 18, which adjusts the sound reproduction system associated with it accordingly.

It is noted that the first terminal 1 is also associated with a sound reproduction system configured in such a way that the apparent location of an origin of sound perceived by a user wearing the earphones 11,12 is adjustable. The first terminal 1 in fact adjusts (step 30) the settings of this sound reproduction system so as to cause the apparent distance between the user of the first terminal 1 and a location of an origin of reproduced sound as perceived by that user to be substantially the same as the apparent distance between the user of the third terminal 18 and a location of an origin of reproduced sound perceived by that other user. This takes account of the fact that, in natural conversation, the physical interpersonal distance and dynamic changes therein are clear to both persons, and form an important non-verbal part of the dynamics of natural conversation.

In other embodiments, only one of the first and third terminals 1,18 is adjusted. Generally, this would be the first terminal 1 as this is the terminal that determines the desired interpersonal distance.

Speech signals are then communicated (step 31) between the first and third terminals 1,18, and reproduced according to the settings.

In the illustrated embodiment, the user of the first terminal 1 (but this could be extended to the user of the third terminal 18) is given the possibility of changing the rendered acoustic interpersonal distance as desired, since the preferred interpersonal distance to a given person may not always be the same. It depends on the mood of the user(s) or dynamics in the social relationship between the communication partners, for instance. Upon receipt of user input via the user controls 6, the first terminal 1 changes (step 32) the target value of the perceived distance to a location of an origin of reproduced sound, in preference to the value associated with the user profile 25 selected initially. The new settings are used to adjust the sound reproduction system associated with the first terminal 1 (step 33), and they are communicated to the third terminal 18 (step 34). The latter step 34 is omitted in one embodiment. In the illustrated embodiment, the steps 32-34 just mentioned may be repeated throughout the duration of the communication session.

In the method illustrated in FIG. 3, a different means of obtaining data representative of at least one indicator of at least an interpersonal relation of a first user to a second user is employed. A first step 35 is, however, the same as the corresponding step 22 in the method of FIG. 2, in that the user selects the desired other user with whom he desires to communicate or the first terminal 1 identifies the user who desires to communicate. In the case of an incoming call, this step 35 may be omitted, and is replaced by a step of receiving a request to establish a connection. In the illustrated case of an outgoing call, the selected user's user record 23 is retrieved from the stored user records 24, in order to retrieve details for establishing a connection, e.g. to the third terminal 18.

The connection is then established (step 36), and sound is communicated (step 37) straightaway. However, the first terminal 1 analyses (step 38) the signal or signals communicating sound between the two users. In one embodiment, it analyses only the signal communicating speech input from the user of the third terminal 18 to the user of the first terminal 1. In another embodiment, it analyses the speech input of both communication partners. It is also possible for the first terminal 1 to analyse only the signal communicating sound originating from the user of the first terminal 1.

A factor influencing people's preferred interpersonal distance is related to the content and/or mood of their conversation. When a conversation is private, people prefer a smaller interpersonal distance than when they are engaging in casual talk. When people are angry or have a heated debate, the preferred distance may be even larger.

In a first embodiment, contents of part or all of the speech communicated between the users of the communication system is semantically analysed. This involves speech recognition and recognition of certain key words that are indicative of a certain type of conversation. Thus, the first terminal 1 is provided with an application for speech-to-text conversion, and with a database of key words and associated data indicative of a social relation of the person uttering the words to the person to whom the words are addressed. Key words recognised within a section of the signal communicating speech are used to determine 39 this relation.

In a second embodiment, at least one property of the at least part of at least one signal communicating sound between the two communication partners is analysed. The analysis is performed on a signal level by analysing, for example, the spectral content, amplitude, or dynamic characteristics of the speech signal. In this way, it might be detected that someone is whispering, in which case a smaller target distance would be preferred, or that someone is shouting, in which case a larger distance might be preferred. Techniques for detecting, for example, aggression, excitement, anger on the basis of speech signal analysis are known. An example is given in Rajput, N., Gupta, P., “Two-Stream Emotion Recognition For Call Center Monitoring”, Proc. Interspeech 2007, Antwerp, Belgium, 2007.

The thus obtained data representative of at least one indicator of at least an interpersonal relation of the at least one first user to the at least one second user is used (step 40) to provide settings according to a pre-determined functional relationship between the indicator or indicators and a preferred interpersonal distance between two persons.

The settings are used to adjust the sound reproduction system associated with the first terminal 1 (step 41) and to remote-adjust the sound reproduction system associated with the third terminal 18 (step 42). Thus, as in the embodiment of FIG. 2, the apparent distance between the user of the first terminal 1 and a location of an origin of reproduced sound as perceived by that user is kept substantially the same as the apparent distance between the user of the third terminal 18 and a location of an origin of reproduced sound as perceived by that other user. In an alternative embodiment, one of the two steps 41,42 is omitted, generally the one leading to adjustment of the apparent distance perceived by the user of the third terminal 18, i.e. the terminal other than the one that performed the signal analysis.

In the embodiment illustrated in FIG. 3, the user of the first terminal 1 (and/or the user of the third terminal 18) is given the possibility of changing the rendered acoustic interpersonal distance as desired. Upon receipt of user input via the user controls 6, the first terminal 1 changes (step 43) the target value of the perceived distance to a location of an origin of reproduced sound. The new settings are used to adjust the sound reproduction system associated with the first terminal 1 (step 44), and they are communicated to the third terminal 18 (step 45), at least in the illustrated embodiment. In other embodiments, this step 45 is omitted, as it may be undesirable to communicate the mood of the person making the adjustment to the user of the third terminal 18. In the illustrated embodiment, the steps 43-45 just mentioned may be repeated throughout the duration of the communication session.

In the same vein, if the user does not override the settings determined by the first terminal through an analysis of the at least one signal communicating sound between the first and the second user, the analysis can be repeated at regular intervals or continually, in order to adapt the perceived interpersonal distance to changes in the relationship between the two communication partners.

In another embodiment, a method combining the methods of FIGS. 2 and 3 is used, in that one of the user profiles 25 is used initially as an indicator of the interpersonal relation of the user of the first terminal 1 to the user of the third terminal 18, and the analysis is used once the communication session has commenced.

It should be noted that the embodiments described above illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

In a conferencing application, the communications between a first and multiple second users of multiple second terminals can be controlled according to the methods outlined above, wherein the indicator of the interpersonal relation of the first to the multiple second users may be determined on the basis of information defining the relation of the first user to each of the second users individually (e.g. he is the customer of an organisation employing the second users), for example. In another embodiment, the methods outlined above are carried out by a central communication processor, rather than in one of the terminals associated with the first or second users.

‘Means’, as will be apparent to a person skilled in the art, are meant to include any hardware (such as separate or integrated circuits or electronic elements) or software (such as programs or parts of programs) which perform in operation or are designed to perform a specified function, be it solely or in conjunction with other functions, be it in isolation or in co-operation with other elements. ‘Computer programme’ is to be understood to mean any software product stored on a computer-readable medium, such as an optical disk, downloadable via a network, such as the Internet, or marketable in any other manner.

1. Method of controlling communications between at least one first and at least one second user of a communication system,
wherein the communication system includes at least a sound reproduction system (13-16,18-20) for audibly reproducing sound communicated by one of the first and second users to the other of the first and second users, which method includes:
obtaining data (23,25) representative of at least one indicator of at least an interpersonal relation of the at least one first user and the at least one second user; and
adjusting the sound reproduction system (13-16,18-20) so as to cause an apparent distance between the other user and a location of an origin of the reproduced sound as perceived by the other user to be adjusted, the apparent distance being determined at least in part according to a pre-determined functional relationship between an indicator of at least an interpersonal relation and a desired interpersonal distance.

2. Method according to claim 1, wherein at least one of the at least one indicator is dependent on the identities of the first and second users.

3. Method according to claim 1, wherein at least part of the data representative of at least one indicator is based on data provided by at least one, of the first and second users.

4. Method according to claim 3, wherein the data provided by at least one of the first and second users includes data associating the other of the first and second users with one of a set of relationship categories (25), each associated with data representative of at least one indicator value.

5. Method according to claim 4, including selecting at least one indicator value in preference to the at least one indicator value associated with the one relationship category in response to user input.

6. Method according to claim 3, wherein data representative of at least one indicator is stored in association with contact details (23,24) for at least one of the first and second users.

7. Method according to claim 1, wherein data representative of at least one indicator is obtained by analysing at least part of at least one signal communicating sound between the first and the second user.

8. Method according to claim 7, including semantically analysing contents of speech communicated between the first and the second user.

9. Method according to claim 7, including analysing at least one signal property of the at least part of at least one signal communicating sound between the first and second user.

10. Method according to claim 1, including adjusting the sound reproduction system (13-16,18-20) so as to cause an apparent location of the origin of the reproduced sound as perceived by the other user to be adjusted in accordance with the interpersonal distance determined according to the functional relationship.

11. Method according to claim 1, wherein the communication system includes a further sound reproduction system (10-12), for audibly reproducing sound communicated by the other user to the one user, wherein both sound reproduction systems are adjusted so as to cause an apparent distance between the one user and a location of an origin of reproduced sound as perceived by the one user and an apparent distance between the other user and a location of an origin of reproduced sound as perceived by the other user to be adjusted to generally the same value.

12. System for controlling communications between at least one first and at least one second user of a communication system,
wherein the communication system includes at least a sound reproduction system (13-16,18-20) for audibly reproducing sound communicated by one of the first and second users to the other of the first and second users, and wherein the system for controlling communications is configured to:
obtain data (23,25) representative of at least one indicator of at least an interpersonal relation of the at least one first user to the at least one second user, and
to adjust the sound reproduction system (13-16,18-20) so as to cause an apparent distance between the other user and a location of an origin of the reproduced sound as perceived by the other user to be adjusted, the apparent distance being determined at least in part according to a pre-determined functional relationship between an indicator of at least an interpersonal relation and a desired interpersonal distance.

13. System for controlling communications between at least one first and at least one second user of a communication system,
wherein the communication system includes at least a sound reproduction system (13-16,18-20) for audibly reproducing sound communicated by one of the first and second users to the other of the first and second users, and wherein the system for controlling communications is configured to:
obtain data (23,25) representative of at least one indicator of at least an interpersonal relation of the at least one first user to the at least one second user, and
to adjust the sound reproduction system (13-16,18-20) so as to cause an apparent distance between the other user and a location of an origin of the reproduced sound as perceived by the other user to be adjusted, the apparent distance being determined at least in part according to a pre-determined functional relationship between an indicator of at least an interpersonal relation and a desired interpersonal distance, configured to execute a method according to claim 1.

14. Computer programme including a set of instructions capable, when incorporated in a machine-readable medium, of causing a system having information-processing capabilities to perform a method according to claim 1.
